(19) United States
(12) Patent Application Publication
(10) Pub. No.: US 2008/0081755 A1
(43) Pub. Date: Apr. 3, 2008

(54) Centrifugal separating-distributing apparatus, centrifugal force generator, and centrifugal separating-distributing method

(75) Inventors: Takeshi Kinpara, Kawasaki-shi (JP); Hajime Sudo, Matsudo-shi (JP); Kenji Ooki, Yokohama-shi (JP); Tomokazu Domon, Yokohama-shi (JP)

Correspondence Address: NIXON & VANDERHYE, PC, 901 NORTH GLEBE ROAD, 11TH FLOOR, ARLINGTON, VA, 22203, US

(73) Assignee: KABUSHIKI KAISHA TOSHIBA, Tokyo (JP)

(21) Appl. No.: 11/724,324

(22) Filed: Mar. 15, 2007

(30) Foreign Application Priority Data
Oct. 2, 2006 (JP) 2006-271057

(51) Int. Cl. B04B 1/16; B01D 43/00; H03B 1/02

(52) U.S. Cl. 494/4; 327/596; 494/37

(57) ABSTRACT

A centrifugal separating-distributing apparatus includes a body being provided with an intake path, a stacking path, and a distributing path. A fluid sample is taken into the intake path, and the sample flows out from an outlet of the path when a first centrifugal force is exerted at a first rotation angle position. Under the first centrifugal force, the flown out sample flows in an inlet of the stacking path and is separated into plural components and the components are stacked in the stacking path. When a second centrifugal force is exerted at a second rotation angle position, a component closest to the inlet of the stacking path flows into an inlet of the distributing path between the outlet of the intake path and the inlet of the stacking path, and is moved away from the inlet to be separated from the remainder of the components in the stacking path.

### CROSS-REFERENCE TO RELATED APPLICATIONS

This application is based upon and claims the benefit of priority from prior Japanese Patent Application No. 2006-271057, filed Oct. 2, 2006, the entire contents of which are incorporated herein by reference.

### BACKGROUND OF THE INVENTION

1. Field of the Invention

An embodiment of this invention relates to a centrifugal separating-distributing apparatus, a centrifugal force generator, and a centrifugal separating-distributing method.

2. Description of the Related Art

A centrifugal separator is used to separate a fluid sample put in a sample vessel into a plurality of components. The components of the fluid sample separated by centrifugal force in the sample vessel are stacked in the direction of the centrifugal force acting in the vessel. In order to perform a variety of tests to a desired component in those separated and stacked in the sample vessel, only the desired component should be extracted from the vessel.

At present, a pipette is usually used to extract the desired component from those in the sample vessel. However, the amount of component which can be handled by the pipette is limited.

When a fluid sample is blood for example, blood cells as a solid component and a blood plasma or serum as a liquid component can be separated from the blood by using a centrifugal separator.

At present, blood of about 10 ml is necessary for various blood tests.

It is difficult to take a blood sample from aged people and infants in comparison with adults, and it is desirable to largely decrease the amount of sample blood necessary for a desired blood test. Further, it is highly demanded to take a blood sample in wide and convenient circumstances.

JP-A 2005-114438 (KOKAI) discloses a test chip and a method for using the test chip, and the test chip separates blood components from each other and collects a predetermined amount of each blood component by micro tubes while the chip is rotated about the same axis.

### BRIEF SUMMARY OF THE INVENTION

A centrifugal separating-distributing apparatus according to one aspect of this invention comprises a sample intake path, a separated-component stacking path and a distributing path. The sample intake path is configured to be taken with a fluid sample to be centrifugally separated, and has a fluid sample outlet through which the fluid sample flows out when a first centrifugal force is exerted at a first rotation angle position. The separated-component stacking path has a fluid sample inlet through which the fluid sample flowed out from the outlet of the sample intake path by the first centrifugal force flows in, and is configured to separate the fluid sample into a plurality of components and to stack the separated components by the first centrifugal force. And, the distributing path has a separated component inlet positioned between the outlet of the sample intake path and the inlet of the separated-component stacking path, and is configured to be distributed with a component from the components stacked in the separated-component stacking path when a second centrifugal force is exerted at a second rotation angle position.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1A is a schematic horizontal sectional view of a centrifugal separating-distributing apparatus according to an embodiment of the invention;

FIG. 1B is an exploded view of the centrifugal separating-distributing apparatus schematically shown in FIG. 1A;

FIG. 2A is an enlarged horizontal sectional view of a predetermined-capacity vessel used in the centrifugal separating-distributing apparatus shown in FIG. 1A;

FIG. 2B is a front view of the vessel shown in FIG. 2A;

FIG. 3A is a schematic horizontal sectional view of the centrifugal separating-distributing apparatus shown in FIG. 1A in a state that blood as a fluid sample is taken in a sample intake path, while a sample intake path and a separated-component stacking path are being orientated to a direction in which centrifugal force acts;

FIG. 3B is a schematic horizontal sectional view showing a state that centrifugal force acts on the centrifugal separating-distributing apparatus shown in FIG. 3A, the blood is flown from the sample intake path into the separated-component stacking path, the blood is separated into blood cells and a blood plasma as blood components in the stacking path, and the blood cells and the blood plasma are stacked in the stacking path;

FIG. 3C is a schematic horizontal sectional view showing a state that the centrifugal separating-distributing apparatus shown in FIG. 3B is rotated to orient a distributing path, instead of the sample intake path and the separated-component stacking path, in the direction in which the centrifugal force acts, and the blood plasma is distributed into the distributing path;

FIG. 3D is a schematic horizontal sectional view showing a state that centrifugal force acts on the centrifugal separating-distributing apparatus shown in FIG. 3C, and the blood plasma in the distributing path is moved away from the blood cells in the separated-component stacking path and collected in a plurality of predetermined-capacity vessels;

FIG. 3E is a schematic horizontal sectional view showing a state that the vessels are removed from the centrifugal separating-distributing apparatus shown in FIG. 3D;

FIG. 4 is a schematic horizontal section view of a modification of the centrifugal separating-distributing apparatus shown in FIGS. 1A and 1B;

FIG. 5A is a schematic plan view showing angle conditions of the sample intake path, the separated-component stacking path, and the distributing path to a centrifugal force acting direction in the centrifugal separating-distributing apparatus according to one aspect of the present invention, the angle conditions being needed for making these paths perform their desirable functions in cooperation with the centrifugal force while the sample intake path and the separated-component stacking path are oriented in the centrifugal force acting direction;

FIG. 5B is a schematic plan view showing angle conditions of the sample intake path, the separated-component stacking path, and the distributing path to the centrifugal force acting direction in the centrifugal separating-distributing apparatus according to the one aspect of the present invention, the angle conditions being needed for making these paths perform their desirable functions in cooperation with the centrifugal force while the distributing path, instead of the sample intake path and the separated-component stacking path, is oriented in the centrifugal force acting direction;

FIG. 6 is a schematic plan view showing tangent vector conditions of a fluid sample or each of separated components in each of the sample intake path, the separated-component stacking path and the distributing path at any positions on an inner surface of each of the sample intake path, the separated-component stacking path and the distributing path, in the centrifugal separating-distributing apparatus according to the one aspect of the present invention, the tangent vector conditions being needed for making the fluid sample or each of the separated components flowing appropriately in each of the sample intake path, the separated-component stacking path and the distributing path by centrifugal force;

FIG. 7 is a schematic plan view showing a condition for preventing components remaining in the separated-component stacking path flowing into the distributing path by centrifugal force in the centrifugal separating-distributing apparatus according to the one aspect of the present invention, while the distributing path, instead of the sample intake path and the separated-component stacking path, is orientated in the direction in which the centrifugal force acts;

FIG. 8A a schematic side view of a centrifugal force generator according to an embodiment of the present invention, the generator being used to exert centrifugal force at first on the sample intake path and the separated-component stacking path and then on the distributing path in the centrifugal separating-distributing apparatus shown in FIGS. 1A and 1B;

FIG. 8B is a schematic plan view showing a gear train for changing a rotation angle position of each of a pair of sample stages within a predetermined range in the centrifugal force generator shown in FIG. 8A;

FIG. 9A is a schematic plan view showing a state that the pair of centrifugal separating-distributing apparatus supported on the pair of sample stages shown in FIG. 8A are set at predetermined rotation angle positions by the gear train shown in FIG. 8B, so that the sample intake path and the separated-component stacking path in each of the pair of centrifugal separating-distributing apparatus are orientated in the centrifugal force acting direction; and

FIG. 9B is a schematic plan view showing a state that the pair of centrifugal separating-distributing apparatus supported on the pair of sample stages shown in FIG. 8A are set at other predetermined rotation angle positions by the gear train shown in FIG. 8B, so that the distributing path, instead of the sample intake path and the separated-component stacking path, in each of the pair of centrifugal separating-distributing apparatus are orientated in the centrifugal force acting direction.

### DETAILED DESCRIPTION OF THE INVENTION

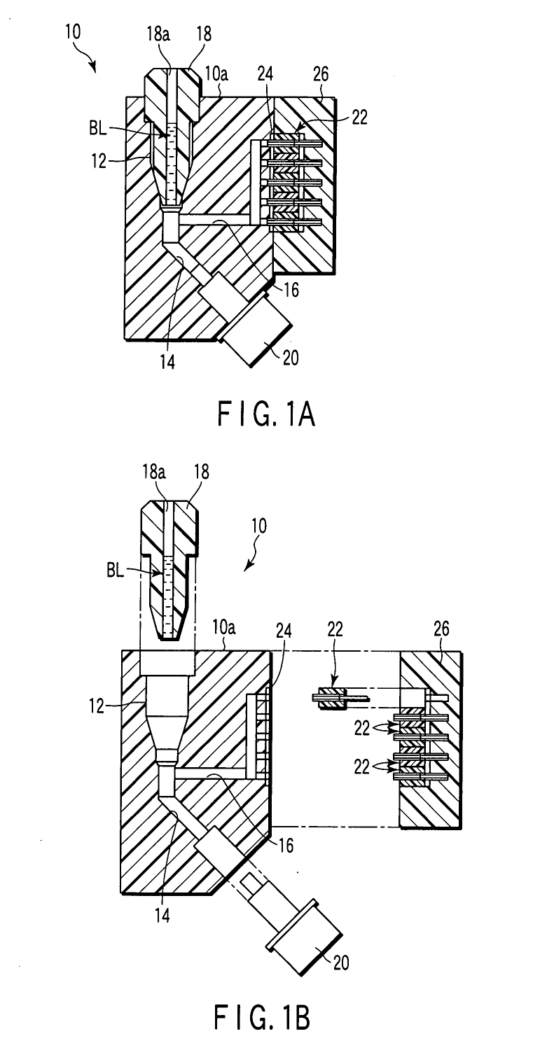

As shown in FIGS. 1A and 1B, a centrifugal separating-distributing apparatus 10 according to an embodiment of this invention is provided with a body 10a including a sample intake path 12, a separated-component stacking path 14, and a distributing path 16, one end of each of these paths being connected with each other.

The sample intake path 12 extends like a straight line and has the other end to be connected removably with a fluid sample holding member 18 holding a fluid sample to be centrifugally separated, blood BL in this embodiment. The fluid sample holding member 18 is removably connected to the other end of the sample intake path 12, for example by frictional fitting, and has a through hole 18a which is arranged concentrically with the other end of the sample intake path 12 when the fluid sample holding member 18 is connected to the other end of the sample intake path 12. The through hole 18a has a capacity of 10 μL.

The one end of the separated-component stacking path 14 is extended straight a little in the extending direction of the sample intake path 12, and then is inclined within 90° (not including 90°), at about 45° in this embodiment, to the extending direction of the sample intake path 12 and is extended straight. The other end of the separated-component stacking path 14, that is, the extending end of the inclined and extended part, is clogged with a plug member 20 which is connected removably to the other end, for example by screwing or frictional fitting. The inclined and extended part of the separated-component stacking path 14 has a capacity of about 6 μL, excluding the part clogged with the plug member 20.

The distributing path 16 is extended at right angles from the sample intake path 12 and the straight part of the separated-component stacking path 14 in a side in which the inclined part of the separated-component stacking path 14 is extended, on a plane including the sample intake path 12 and separated-component stacking path 14. The other end, or the extending end, of the distributing path 16 is opened in the outer surface of the body 10a, and is configured to be removably attached with at least one vessel 22 of predetermined capacity. In this embodiment, the other end of the distributing path 16 is branched into several portions which are arranged in parallel to each other.

The branched parallel portions of the other end of the distributing path 16 are removably and liquid-tightly connected to vessels 22 with a sealing member 24, and each of these vessels 22 has the same size and capacity as to each other. Each vessel 22 has a capacity of about 110 nL.

The vessels 22 are removably held by a vessel holding member 26, and are arranged in parallel to each other. The vessel holding member 26 is configured to be removably fixed to a predetermined part in which the parallel branches of the other end of the distributing path 16 are opened on the outside surface of the body 10a. While the vessel holding member 26 is separated from the predetermined part on the outer surface of the body 10a as shown in FIG. 1B, it is easily possible to make the vessels 22 being held in the vessel holding member 26 in a predetermined order and to remove the vessels 22 easily from the vessel holding member 26. Further, by fixing the vessel holding member 26 to the predetermined part on the outer surface of the main body 10a while the vessel holding member 26 holds the vessels 22 in the predetermined order as shown in FIG. 1A, all of the vessels 22 can be connected to all of the parallel branches of the other end of the distributing path 16 at one time.

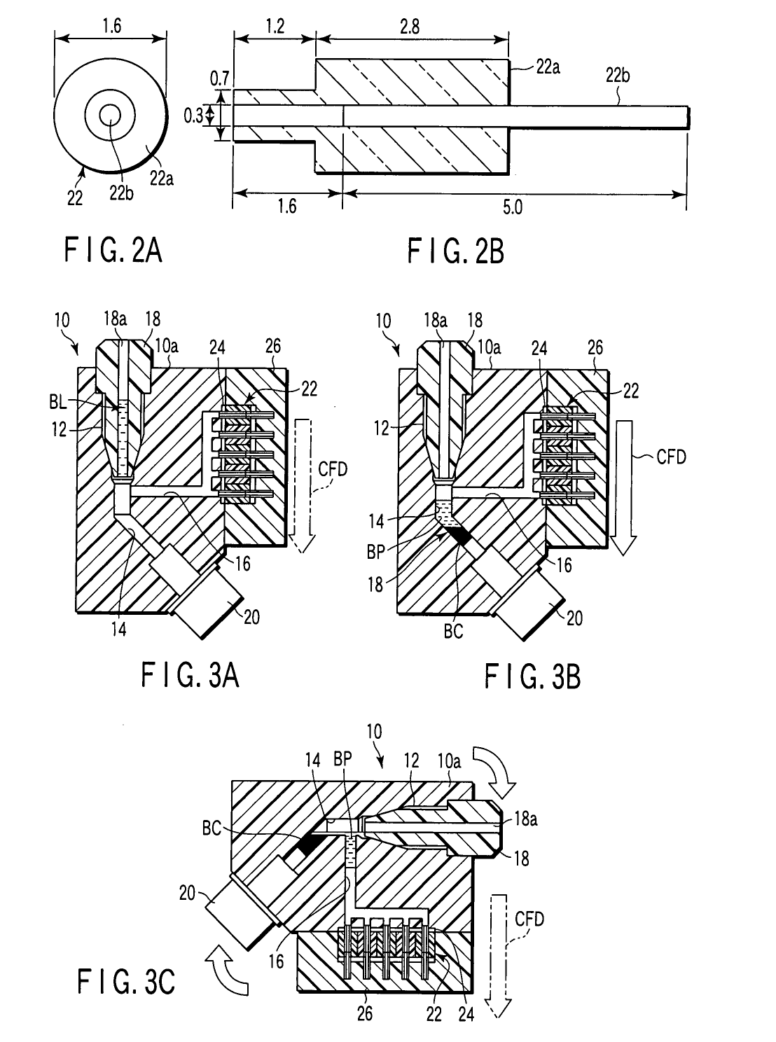

As shown in FIGS. 2A and 2B, the vessel 22 includes a stepped cylindrical vessel body 22a, and a piston 22b one end of which is inserted slidably and liquid-tightly into a hole of the vessel body 22a. The other end of the piston 22b is projected to the outer space by a predetermined distance from an opening of the hole in the large diameter part of the vessel body 22a to provide a hollow with a predetermined capacity (about 110 nL) in a portion of the hole extending from an opening of the hole in the small diameter part of the vessel body 22a to the one end of the piston 22b. FIGS. 2A and 2B show an example of the dimensions of the vessel 22 in units of millimeters.

All structural members of the centrifugal separating-distributing apparatus 10 according to the embodiment of this invention and described above with reference to FIGS. 1A and 1B are made of synthetic resin and disposable.

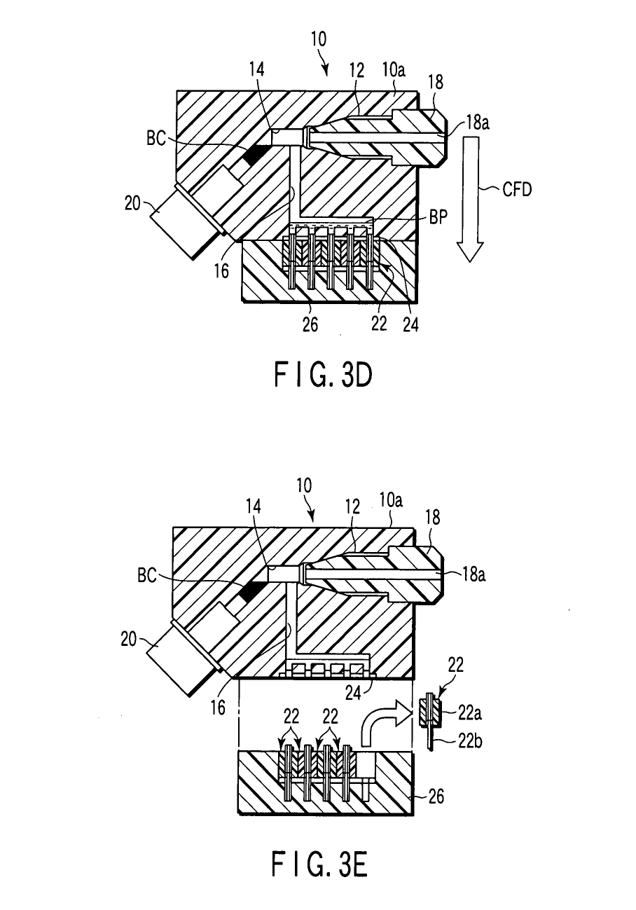

Next, a centrifugal separating-distributing method using the centrifugal separating-distributing apparatus 10 according to the embodiment of this invention and described above with reference to FIGS. 1A and 1B will be explained by referring to FIGS. 3A to 3E.

The fluid sample holding member 18 holding a fluid sample to be centrifugally separated, blood BL in this embodiment, is removably connected to the other end of the sample intake path 12 of the centrifugal separating-distributing apparatus 10 while the vessel holding member 26 holding empty vessels 22 is fixed to the predetermined part on the outer surface of the body 10a. Then, the centrifugal separating-distributing apparatus 10 is removably fixed to a predetermined position of a not-shown and well known centrifugal force generator.

The centrifugal force generator includes a rotation member connected to a rotation drive source, such as an electric motor, and a sample stage mounted on an upper surface of the rotation member. The sample stage is rotatable within a rotation angle range of 90° with respect to the upper surface of the rotation member, and is selectively fixable to one end or the other end of the rotation angle.

The centrifugal separating-distributing apparatus 10 is placed on and removably fixed to the sample stage. In this time, the centrifugal separating-distributing apparatus 10 is placed on the sample stage so that the sample intake path 12, the separated-component stacking path 14 and the distributing path 16 are laid on an imaginary plane orthogonal to a rotation center shaft of the rotation member. Further, as shown in FIG. 3A, the centrifugal separating-distributing apparatus 10 is placed on the sample stage so that the sample intake path 12 and the one end of the separated-component stacking path 14 extending straight to the sample intake path 12 are substantially in parallel to a radial direction of the rotation center shaft. The radial direction is a direction CFD in which a centrifugal force generated in the centrifugal separating-distributing apparatus 10 when the rotation member is rotated is directed.

Then, the rotation member of the centrifugal force generator is rotated in a predetermined direction at a predetermined rotation number. This rotation of the rotation member exerts a first centrifugal force along the centrifugal force direction CFD on the blood BL in the through hole 18a of the fluid sample holding member 18 connected to the sample intake path 12 of the centrifugal separating-distributing apparatus 10, and the first centrifugal force makes the blood BL flow out from the through hole 18a into the one end of the separated-component stacking path 14 through the one end of the sample intake path 12, as shown in FIG. 3B. This means that the one end of the sample intake path 12 serves as a fluid sample outlet through which the blood BL as the fluid sample flows out by the centrifugal force, and the one end of the separated-component stacking path 14 serves as a fluid example inlet through which the blood BL as the fluid sample flown out from the fluid sample outlet flows in.

The first centrifugal force also exerts on the blood BL flown into the separated-component stacking path 14 at its other end clogged with the plug member 20, and the blood BL is separated into a plurality of components, for example, blood cells BC and the like as a solid component and blood plasma (or serum) as a liquid component. The solid component including the blood cells BC and the like and the liquid component including the blood plasma BP are stacked on the other end of the separated-component stacking path 14 owing to a difference in their density. In this time, the solid component including the blood cells BC and the like with a large density are placed in the inclined part at the other end of the separated-component stacking path 14, and the liquid component including the blood plasma with a small density is placed at a position closer to the one end of the separated-component stacking path 14 than the solid component including the blood cells BC and the like. More particularly, the liquid component including the blood plasma BP is placed from a position close to the inlet of the inclined part of the separated-component stacking path 14 to a position of the straight part of the separated-component stacking path 14 just before the distributing path 16.

Then, the rotation of the rotation member of the centrifugal force generator is stopped, and the stage is rotated by 90° to the rotation member. After this rotation, the stage is fixed again to the rotation member. In the centrifugal separating-distributing apparatus 10 rotated together with the sample stage, the distributing path 16, instead of the sample intake path 12 and the straight part at the one end of the separated-component stacking path 14, is placed substantially in parallel to the direction CFD in which the centrifugal force generated in the centrifugal separating-distributing apparatus 10 when the rotation member is rotated is directed, as shown in FIG. 3C.

By this rotation of the centrifugal separating-distributing apparatus 10, the liquid component including the blood plasma BP in the separated-component stacking path 14 is distributed into the one end of the distributing path 16, and the solid component including the blood cells BC and the like are left in the inclined part and are not flown into the straight part beyond the boundary between the inclined part and straight part. In this time, the one end of the distributing path 16 which is positioned between the fluid sample outlet of the one end of the sample intake path 12 and the fluid sample inlet of the one end of the separated-component stacking path 14 functions as an separated component inlet.

Next, the rotation of the rotation member of the centrifugal force generator is started again. This rotation of the rotation member exerts a second centrifugal force directed in the centrifugal force direction CFD on the liquid component including the blood plasma BP. By the second centrifugal force, the liquid component including the blood plasma BP is moved away from the one end to the other end in the distributing path 16, and is separated from the solid component including the blood cells BC and the like and remained in the separated-component stacking path 14. The liquid component including the blood plasma BP reached at the other end of the distributing path 16 sequentially fills the holes of the vessels 22 at the other end.

Next, the rotation of the rotation member of the centrifugal force generator is stopped again. Then, the vessel holding member 26 is removed from the centrifugal separating-distributing apparatus 10 placed on the sample stage of the rotation member, as shown in FIG. 3E, and the vessels 22 with the holes of the vessel bodies 22a being filled with the liquid component including the blood plasma BP can be removed from the vessel holding member 26. The amount of liquid component including the blood plasma filled in the hole of each vessel body 22a of the vessels 22 is equal to each other. The predetermined amount of liquid component including the blood plasma BP and filled in the hole of the vessel body 22a of the vessel 22 can be pushed out from the hole of the vessel body 22a by pressing the piston 22b toward the small diameter part of the vessel body 22a.

The solid component including the blood cells BC and the like and remained in the inclined part of the separated-component stacking path 14 can be easily collected from the inclined part by removing the plug member 20 from the other end of the separated-component stacking path 14.

The following is apparent from the above description with reference to FIGS. 3A to 3E. After the centrifugal separating-distributing apparatus 10 with the vessel holding member 26 holding the empty vessels 22 and the fluid sample holding member 18 holding blood BL is fixed to the sample stage of the rotation member of the centrifugal force generator, as shown in FIG. 3A, the rotation of the rotation member, the rotation stop of the rotation member and the 90° rotation-of the sample stage, the re-rotation of the rotation member, and the re-rotation stop of the rotation member can be performed automatically.

During this automatic operation, the separation of the plurality of components, the solid component including the blood cells BC and the like and the liquid component including the blood plasma BP in this embodiment, from the blood BL, the distribution of the one component including the blood plasma BP from the other component including the blood cells BC and the like, and the collection of the predetermined amount of the distributed component including the blood plasma BL can be performed automatically in the centrifugal separating-distributing apparatus 10.

Therefore, even if the amount of blood BL as a fluid sample to be prepared is largely decreased compared with the conventional amount, a largely decreased amount of component including the blood cell BC and the like and that of the blood plasma BP can be collected easily and respectively after these components are separated from such a largely decreased amount of the fluid sample by the centrifugal force.

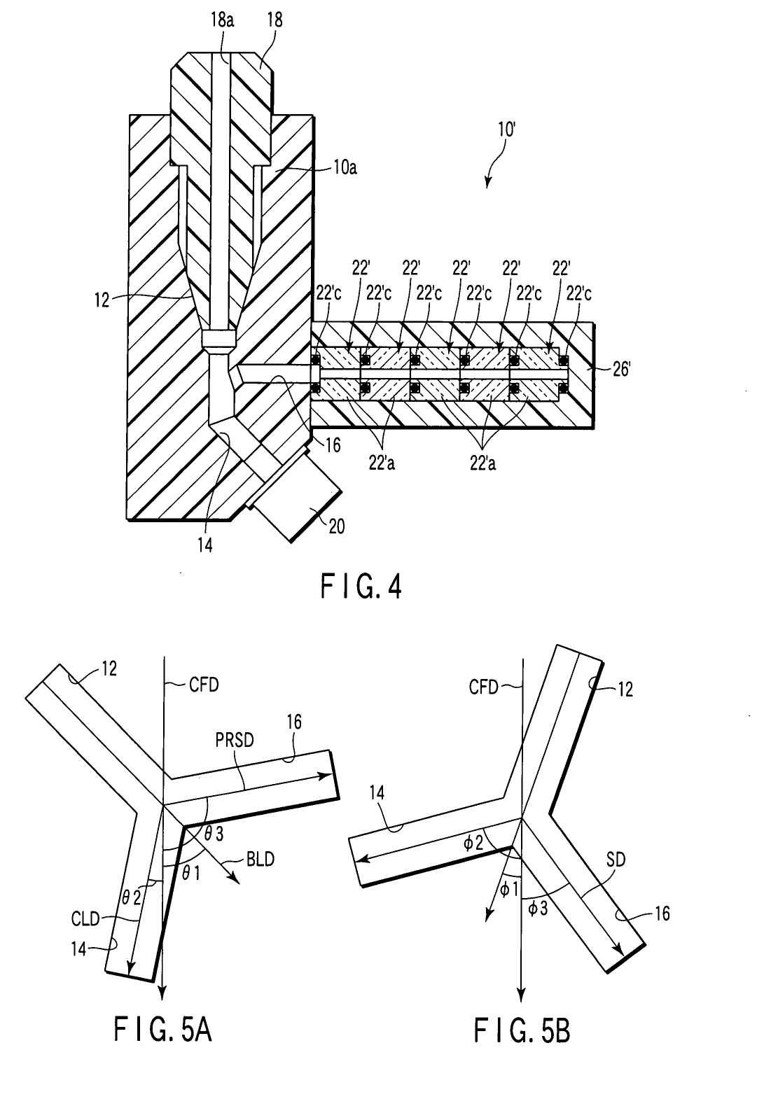

Next, a centrifugal separating-distributing apparatus 10′ according to a second embodiment of this invention will be explained with reference to FIG. 4.

Most of the structural members of the centrifugal separating-distributing apparatus 10′ according to the second embodiment are the same as those of the centrifugal separating-distributing apparatus 10 according to the first embodiment shown in FIGS. 1A and 1B. Therefore, the same members of the centrifugal separating-distributing apparatus 10′ as those of the centrifugal separating-distributing apparatus 10 are designated by the same reference numerals designating those of the centrifugal separating-distributing apparatus 10, and are not explained in detail.

The centrifugal separating-distributing apparatus 10′ is different from the centrifugal separating-distributing apparatus 10 in that the other end of the distributing path 16 is not branched into several portions. A vessel holding member 26′ is removably fixed to a predetermined part in which the other end of the distributing path 16 is opened, on the outer surface of the body 10a of the centrifugal separating-distributing apparatus 10′. The vessel holding member 26′ removably holds vessels 22′ arranged adjacent to each other coaxially and linearly in the extending direction of the distributing path 16. Each vessel 22′ has the same shape and dimensions as to each other, and includes a stepped cylindrical vessel body 22′a having a large diameter part and a small diameter part. A circular shaped depression with a diameter larger than the small diameter part is formed in the end surface of the large diameter part opposite to the small diameter part. A ring shaped sealing member 22′c is fit on the outer circumference of the small diameter part of each vessel 22′. The vessels 22′ are arranged coaxially and linearly in the vessel holding member 26′ by inserting the small diameter part of the vessel body 22′a with the sealing member 22′c into the depression of the large diameter part of the vessel body 22′a of the adjacent vessel 22′. The sealing members 22′c of the vessels 22′ hermetically connect the center holes of the vessels 22′ with each other, and the center holes are defined as collecting pots of predetermined capacities being equal to each other. The ring shaped sealing member 22′c is also placed in the depression of the large diameter part of the outermost vessel 22′ in the vessel holding member 26′, which is faced to the opening of the other end of the distributing path 16 when the vessel holding member 26′ is fixed to the predetermined part on the outer surface of the main body 10a of the centrifugal separating-distributing apparatus 10′. This sealing member 22′c ensures the sealed connection of the hole of the outermost vessel 22′ to the opening at the other end of the distributing path 16 in the predetermined part.

The centrifugal separating-distributing apparatus 10′ of the second embodiment is used as the centrifugal separating-distributing apparatus 10 of the first embodiment. Namely, the apparatus 10′ can be used to separate blood BL held by the fluid sample holding member 18 connected to the sample intake path 12, into the solid component including the blood cells BC and the like and the liquid component including the blood plasma BP by using a centrifugal force. Then, the apparatus 10′ can be used to distribute the liquid component including the blood plasma BP from the solid component including the blood cells BC and the like, and to collect the distributed component at the other end of the distributing path 16, by using the centrifugal force. Further, the apparatus 10′ can collect the predetermined amount of distributed component in the hole of each of the vessels 22′.

The centrifugal separating-distributing apparatus 10′ of the second embodiment can obtain the same technical advantages as those obtained by the centrifugal separating-distributing apparatus 10 of the first embodiment.

In each of the centrifugal separating-distributing apparatuses 10 and 10′ according to the first and second embodiments, the one end of the sample intake path 12 and that of the separated-component stacking path 14 are linearly arranged, the inclined part including the other end of the separated-component stacking path 14 is inclined at 45° to the one end of the separated-component stacking path 14, and the distributing path 16 crosses the one end of the sample intake path 12 and that of separated-component stacking path 14 at an angle of 90° in the inclined part side of the separated-component stacking path 14.

However, according to this invention, the sample intake path 12, the separated-component stacking path 14, and the distributing path 16 should satisfy the following conditions in each of the centrifugal separating-distributing apparatuses 10 and 10′.

When the first centrifugal force is exerted in the direction CFD as shown in FIG. 5A:

a first angle θ1 formed between the direction CFD in which the first centrifugal force is directed and a direction BLD in which the blood BL as an example of a fluid sample is moved toward the fluid sample outlet at the one end of the sample intake path 12 in the sample intake path 12 by the first centrifugal force, is less than 90°;

a second angle θ2 formed between the direction CFD in which the first centrifugal force is directed and a direction CLD in which the blood cells BC and the like and the blood plasma BP as examples of components separated from the blood BL as an example of the fluid sample by the first centrifugal force are stacked in the separated-component stacking path 14, is less than 90°; and

a third angle θ3 formed between the direction CFD in which the first centrifugal force direction is directed and a direction (pre-distributing direction) PRSD in which a distributing direction is directed while the separated-component stacking path 14 is directed in the direction CFD, is greater than or equal to 90° and less than 180°, in the distributing direction the blood plasma BP as one example of the separated components being moved away from a separated component inlet at the one end of the distributing path 16 by the first centrifugal force after the distributing path 16 is directed in the direction CFD and the blood plasma BP is distributed into the distributing path 16.

When the second centrifugal force is exerted in the direction CFD as shown in FIG. SB:

a fourth angle φ2 formed between the direction CFD in which the second centrifugal force is directed and a direction (post-component stacking direction) POCLD in which the component stacking direction (CLD in FIG. 5A) in the separated-component stacking path 14 is directed after the distributing path 16 is directed in the direction CFD, is less than 90°; and

a fifth angle φ3 formed between the direction CFD and the distributing direction SD is less than 90°.

Further, the whole of the sample intake path 12, the straight part at the one end of the separated-component stacking path 14 and the inclined part including the other end of the separated-component stacking path 14, and the whole of the distributing path 16 may not be straight, and may be curved as long as the following conditions are satisfied.

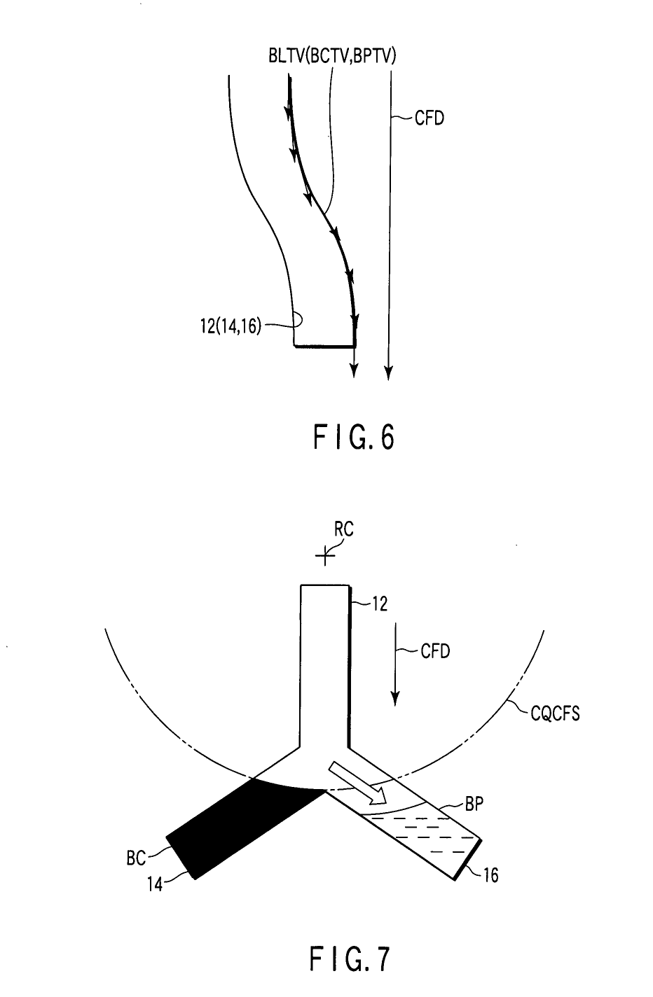

As shown in FIG. 6;

an angle formed between the direction CFD and a tangential vector BLTV is less than 90°, wherein the tangential vector BLTV is generated at any position on the inner surface of the sample intake path 12 by the blood BL as one example of the fluid sample which is moved by the centrifugal force toward the fluid sample outlet at the one end of the sample intake path 12 in the sample intake path 12;

an angle formed between the direction CFD and a tangential vector BCTV is less than 90°, wherein the tangential vector BCTV is generated at any position on the inner surface of the separated-component stacking path 14 by the blood cells BC and the like and the blood plasma BP as examples of components which are separated from the blood BL as the example of the fluid sample by the centrifugal force and which are stacked in the separated-component stacking path 14;

an angle formed between the direction CFD and a direction in which a tangential vector BPTV is directed while the separated-component stacking path 14 is directed in the CFD is greater than or equal to 90° and less than 180°, wherein the tangential vector BPTV is generated at any position on the inner surface of the distributing path 16 by the blood plasma BP as the example of the component which is distributed in the distributing path 16 after the distributing path 16 is directed to the centrifugal force direction CFD and which is moved away from the separated component inlet as the one end of the distributing path 16 by the centrifugal force;

an angle formed between the direction CFD and a direction in which a tangential vector BCTV is directed after the distributing path 16 is directed in the direction CFD is less than 90°, wherein the tangential vector BCTV is generated at any position on the inner surface of the separated-component stacking path 14 by the blood cells BC and the like and the blood plasma BP as the examples of the components which are separated from the blood BL as the example of the fluid sample and which are stacked in the separated-component stacking path 14, by the centrifugal force; and

an angle formed between the CFD and a tangential vector BPTV is less than 90°, wherein the tangential vector BPTV is generated at any position on the inner surface of the distributing path 16 by the blood plasma BP as the example of the component which is distributed into the distributing path 16 after the distributing path 16 is directed in the direction CFD and which is moved away from the separated component inlet as the one end of the distributing path 16, by the centrifugal force.

Further, according to this invention, the sample intake path 12, the 1 separated-component stacking path 14, and the distributing path 16 must satisfy the following conditions in each of the centrifugal separating-distributing apparatuses 10 and 10′.

As shown in FIG. 7, in order to distribute the blood plasma BP as the example of the component into the distributing path 16 from the blood cells and the like BC as the examples of the remaining components in the blood cells and the like BC and the blood plasma BP as the examples of the components separated from the blood BL as an example of the fluid sample in the separated-component stacking path 14, it is necessary to revolve each of the centrifugal separating-distributing apparatuses 10 and 10′ of the first and second embodiments around the rotation center RC of the rotation member by the rotation member of the centrifugal force generator in a state that the distributing path 16 is directed in the direction CFD. In this time, as shown in FIG. 7, an equal centrifugal force surface EQCFS generated on the surface of the blood cells BC and the like in the separated-component stacking path 14 must not be beyond a position where the one end of the distributing path 16 crosses the one end of the separated-component stacking path 14.

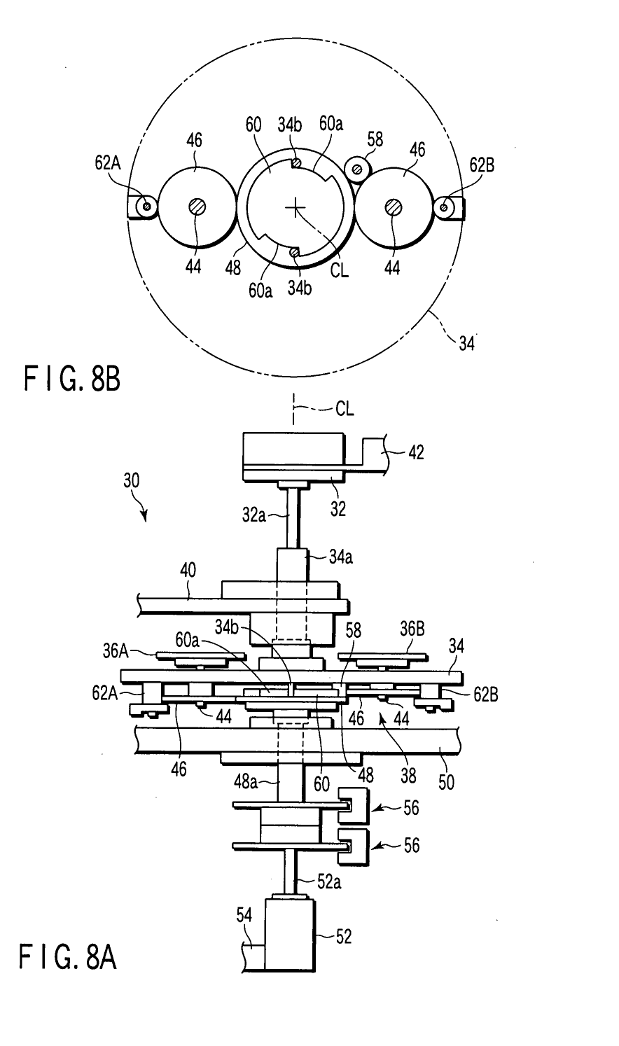

Next, a centrifugal force generator 30 according to an embodiment of the invention will be explained with reference to FIGS. 8A and 8B. The centrifugal force generator 30 is used to exert centrifugal force on the sample intake path 12 and separated-component stacking path 14, and then on the distributing path 16 in the centrifugal separating-distributing apparatus 10 shown in FIGS. 1A and 1B.

The centrifugal force generator 30 has a rotation member 34 which is rotated about a predetermined rotation center line CL by a rotation force transmitted from a rotation drive source 32. At least one pair, one pair in this embodiment, of sample stages 36A and 36B is arranged symmetrical to the rotation center line CL on the rotation member 34. And, a sample rotation mechanism 38 is interposed between the rotation member 34 and the sample stages 36A and 36B to rotate the sample stages 36A and 36B in directions exactly opposite to each other between a predetermined first rotation angle position and a predetermined second rotation angle position.

Each of the sample stages 36A and 36B can hold and removably fix the centrifugal separating-distributing apparatus 10 thereon, so that the sample intake path 12, the separated-component stacking path 14 and the distributing path 16 of the apparatus 10 are placed in an imaginary plane which crosses the rotation center line CL, at an angle of 90° in this embodiment. Each of the sample stages 36A and 36B revolves around the rotation center line CL by the rotation of the rotation member 34.

The rotation member 34 is formed like a circular plate, and has a rotation center shaft 34a extending upward in the vertical direction. The rotation center shaft 34a is rotatably supported by a first rotation center shaft support 40 through a not-shown bearing. The rotation drive source 32 is supported by a first rotation drive source support 42 above the rotation member 34, and includes a bi-directional motor. An output shaft 32a of the bi-directional motor is connected to the upper end of the rotation center shaft 34a.

Each of the sample stages 36A and 36B is placed on the upper surface of the rotation member 34, and has a rotation center shaft 44 extending in parallel to and in the same direction as the rotation center line CL. The rotation center shaft 44 is rotatably supported by the rotation member 34, and a rotation force input gear 46 is concentrically fixed to the rotation center shaft 44 in the lower surface side of the rotation member 34.

A sample stage rotation drive gear 48 is arranged concentrically with the rotation member 34 below the rotation member 34. The sample stage rotation drive gear 48 has a rotation center shaft 48a extending downward in the vertical direction. The rotation center shaft 48a is rotatably supported by a second rotation center shaft support 50 through a not-shown bearing. Below the second rotation center shaft support 50, a sample stage rotation drive source 52 is supported by a second rotation drive source support 54. The sample stage rotation drive source 52 includes a bi-directional stepping motor. An output shaft 52a of the bi-directional stepping motor is connected to the lower end of the rotation center shaft 48a. Rotary encoders 56 are attached to the rotation center shaft 48a.

The sample stage rotation drive gear 48 meshes directly with the rotation force input gear 46 of one sample stage 36A, and meshes indirectly with the rotation force input gear 46 of the other sample stage 36B through a reversing gear 58 rotatably supported on the lower surface of the rotation member 34. When the sample stage rotation drive gear 48 is rotated in one direction, the sample stage 36B is rotated in the same direction and the sample stage 36A is rotated in the other opposite direction. However, the number of the teeth of the rotation force input gear 46 of the sample stage 36A, that of the reversing gear 58, and that of the rotation force input gear 46 of the sample stage 36B are set so that the rotation angle of the sample stage 36A and that of the sample stage 36B are equal to each other.

A pair of connection pins 34b is fixed to the lower surface of the rotation member 34 to be symmetrical with respect to the rotation center line CL. A cam member 60 is fixed to the upper surface of the sample stage rotation drive gear 48. The cam member 60 has a pair of cam grooves 60a each of which extends at a predetermined rotation angle on an imaginary circle concentric with the rotation center line CL. The cam grooves 60a are arranged symmetric with respect to the rotation center line CL.

A not-shown clutch member is interposed between the upper surface of the cam member 60 and the lower surface of the rotation member 34.

On the lower surface of the rotation member 34, a pair of eccentric weight gears 62A and 62B is rotatably supported. The eccentric weight gears 62A and 62B are arranged in outsides of the rotating input gears 46 on a straight line connecting the rotation center line CL to the rotation center lines of the rotation center shafts 44 of the rotation input gears 46. One eccentric weight gear 62A meshes with one rotation input gear 46, and the other eccentric weight gear 62B meshes with the other rotation input gear 46.

The sample stage rotation mechanism 38 includes the rotation member 34 with the came member 60 having a pair of cam grooves 60a cooperating with a pair of connection pins of the rotation member 34, a pair of rotation force input gears 46 of a pair of sample stages 36A and 36B, and the reversing gear 58.

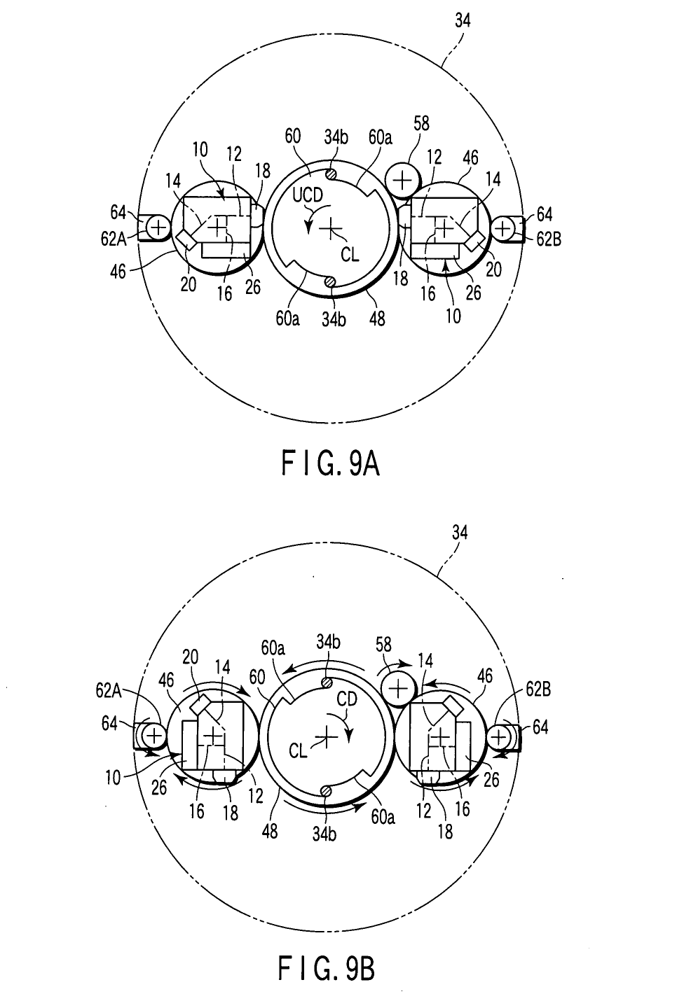

Next, by referring to FIGS. 9A and 9B, the operation of the centrifugal force generator 30 explained with reference to FIGS. 8A and 8B will be explained.

FIG. 9A shows an initial state of the centrifugal force generator 30. In this state, an operation of the rotation drive source 32 for the rotation member 34 and an operation of the sample rotation drive source 52 for the sample stage rotation drive gear 48 are stopped, and the pair of eccentric weight gears 62A and 62B arranges their eccentric weights 64 exactly opposite to each other in the radial direction of the rotation center line CL. Each connection pin 34b on the lower surface of the rotation member 34 contacts each cam groove 60a of the cam member 60 at its end in a counterclockwise direction when the sample stage rotation drive source 52 is viewed from the rotation drive source 32 as shown in FIG. 9A. The not-shown clutch member between the cam member 60 and the rotation member 34 connects the cam member 60 and the rotation member 34 with each other so that the cam member 60 and the rotation member 34 can rotate as one body. The rotation angle position of each of the sample stages 36A and 36B on the rotation member 34 at this time is defined as a first rotation angle position.

During this state, the pair of centrifugal separating-distributing apparatuses 10 is placed on and removably fixed to the pair of sample stages 36A and 36B as shown in FIG. 9A, and blood as a fluid sample has already taken into the sample intake path 12 of each centrifugal separating-distributing apparatuses 10 by the fluid sample holding member 18.

Namely, each centrifugal separating-distributing apparatus 10 is arranged so that the sample intake path 12 and the straight part of the separated-component stacking path 14 are directed inward in the radial direction of the rotation center line CL. Refer to FIG. 3A.

Next, power is applied to the rotation drive source 32 for the rotation member 34, and not applied to the sample stage rotation drive source 52 for the sample stage rotation drive gear 48. As a result, the rotation member 34 is rotated counterclockwise as indicated by an arrow UCD in FIG. 9A, and the centrifugal separating-distributing apparatuses 10 on the pair of sample stages 36A and 36B are revolved counterclockwise around the rotation center line CL in the UCD direction.

During this time, the rotation of the rotation member 34 is transmitted to the cam member 60 by the not-shown clutch member, and the cam member 60 is rotated together with the rotation member 34. Therefore, while the rotation member 34 rotates, the sample stage rotation drive gear 48 does not rotate relative to the rotation member 34. And, the eccentric weight gears 62A and 62B are held by centrifugal force exerted on the eccentric weights 64 so that the eccentric weights 64 are faced exactly opposite to each other in the radial direction of the rotation center line CL. The eccentric weight gears 62A and 62B do not rotate relative to the rotation member 34. As a result, each of the sample stages 36A and 36B on which the pair of centrifugal separating-distributing apparatuses 10 are fixed, does not rotate relative to the rotation member 34.

The blood BL held in the fluid sample holding member 18 connected to the sample intake path 12 of the centrifugal separating-distributing apparatus 10 flows into the separated-component stacking path 14 through the fluid sample inlet from the fluid sample outlet as the one end of the sample intake path 12 by the centrifugal force. The blood BL in the separated-component stacking path 14 is separated into the solid component including the blood cells BC and the like and the liquid component including the blood plasma BP by the centrifugal force, and these separated components are stacked in the separated-component stacking path 14. Refer to FIG. 3B.

Next, power supply to the rotation drive source 32 for the rotation member 34 is stopped, and the rotation of the rotation member 34 is stopped. In this state, the centrifugal force does not exert on the pair of centrifugal separating-distributing apparatuses 10, so that the liquid component including the blood plasma BP being closer to the one end of the distributing path 16 in the separated and stacked liquid and solid components including the blood cells BC and the like and the blood plasma BP in the separated-component stacking path 14 can flow into the separated component inlet at the one end of the distributing path 16.

At the same time, the not-shown clutch member between the rotation member 34 and the cam member 60 is released. Thereafter, power is supplied to the sample stage rotation drive source 52 for the sample stage rotation drive gear 48, and the sample stage rotation drive gear 48 is rotated counterclockwise relative to the rotation member 34 as indicated by the arrow UCD in FIG. 9A. This rotation of the sample stage rotation drive gear 48 is stopped when each of the connection pins 34b on the lower surface of the rotation member 34 comes in contact with each of the cam grooves 60a of the cam member 60 at its end positioned in the clockwise direction when the sample stage rotation drive source 52 is viewed from the rotation drive source 32 as shown in FIG. 9B. Further, the not-shown clutch member between the cam member 60 and the rotation member 34 connects again the cam member 60 and the rotation member 34 with each other so that the cam member 60 and the rotation member 34 can rotate as one body.

The rotation of the sample rotation drive gear 48 is transmitted to the rotation force input gears 46 of the sample stages 36A and 36B directly or indirectly through the reversing gear 58. As a result, the rotation force input gear 46 of one sample stage 36A is rotated clockwise by 90° from the first rotation angle position shown in FIG. 9A, and the rotation force input gear 46 of the other sample stage 36B is rotated counterclockwise by 90° from the first rotation angle position shown in FIG. 9A. Further, the rotation of the rotation force input angle of each of the sample stages 36A and 36B makes one rotation of each of the eccentric weight gears 62A and 62B. That is, after this one rotation, the eccentric weight gears 62A and 62B are arranged so that the eccentric weights 64 are faced exactly opposite to each other in the radial direction of the rotation center line LC as shown in FIG. 9B, like in the case shown in FIG. 9A.

Each of the centrifugal separating-distributing apparatuses 10 on the sample stages 36A and 36B rotated clockwise or counterclockwise by 90° from the first rotation angle position shown in FIG. 9A directs the distributing path 16, instead of the sample intake path 12 and the straight part of the separated-component stacking path 14, outward in the radial direction of the rotation center line CL as shown in FIG. 9B. The rotation angle position of each of the sample stages 36A and 36B on the rotation member 34 at this time is defined as a second rotation angle position.

Next, power is supplied again to the rotation drive source 32 for the rotation member 34 in the reverse direction, and is not applied to the sample stage rotation drive source 52 for the sample stage rotation drive gear 48. As a result, the rotation member 34 is rotated clockwise as indicated by the arrow CD in FIG. 9B, contrary to the situation shown FIG. 9A, and the centrifugal separating-distributing apparatuses 10 on the sample stages 36A and 36B are revolved clockwise around the rotation center line CL.

At this time, the rotation of the rotation member 34 is transmitted to the cam member 60 by the not-shown clutch member, and the cam member 60 is rotated together with the rotation member 34. Therefore, while the rotation member 34 rotates, the sample stage rotation drive gear 48 does not rotate relative to the rotation member 34. And, the eccentric weight gears 62A and 62B are held by the centrifugal force exerted on the eccentric weights 64 so that the eccentric weights 64 are faced exactly opposite to each other in the radial direction of the rotation center line CL. The eccentric weight gears 62A and 62B do not rotate relative to the rotation member 34. As a result, each of the sample stages 36A and 36B on which the centrifugal separating-distributing apparatuses 10 are fixed does not rotate relative to the rotation member 34.

In each centrifugal separating-distributing apparatus 10, the blood plasma BP as one component positioned close to the one end of the distributing path 16 in the separated-component stacking path 14 by the last time centrifugal force and then flowed into the separated component inlet at the one end of the distributing path 16, is moved away from the one end to the other end in the distributing path 16 by the centrifugal force. As a result, the blood plasma BP is completely distributed from the blood cells BC and the like as the other component remained at the other end close to the plug member 20 in the separated-component stacking path 14. The blood plasma BP reached at the other end of the distributing path 16 is collected in a predetermined amount into each of the vessels 22 held in the vessel holding member 26. Refer to FIG. 3D.

Next, power supply to the rotation drive source 32 for the rotation member 34 is stopped, and the rotation of the rotation member 34 is stopped. After the centrifugal force does not exert on the centrifugal separating-distributing apparatuses 10, the blood cells BC and the like as the other component remained at the other end of the separated-component stacking path 14 close to the plug member 20, do not flow into the separated component inlet at the one end of the distributing path 16.

Further, the not-shown clutch member between the rotation member 34 and the cam member 60 is released. Thereafter, power is applied to the sample stage rotation drive source 52 for the sample stage rotation drive gear 48, and the sample stage rotation drive gear 48 is rotated clockwise relative to the rotation member 34 as indicated by the arrow CD in FIG. 9B. This relative rotation of the sample stage rotation drive gear 48 is stopped when each of the connection pins 34b on the lower surface of the rotation member 34 contacts each of the cam grooves 60a of the cam member 60 at its end in the counterclockwise direction when the sample stage rotation drive source 52 is viewed from the rotation drive source 32 as shown in FIG. 9A. The not-shown clutch member between the cam member 60 and the rotation member 34 connects the cam member 60 and the rotation member 34 so that the cam member 60 and the rotation member 34 can rotate as one body.

The rotation of the sample rotation drive gear 48 is transmitted to the rotation force input gear 46 of each of the sample stages 36A and 36B directly or indirectly through the reversing gear 58. The rotation force input gear 46 of one sample stage 36A is rotated counterclockwise by 90° from the second rotation angle position shown in FIG. 9B to the first rotation angle position shown in FIG. 9A, and the rotation force input gear 46 of the other sample stage 36B is rotated clockwise by 90° from the second rotation angle position shown in FIG. 9B to the first rotation angle position shown in FIG. 9A. Further, the rotation of the rotation force input gear 46 of each of the sample stages 36A and 36B makes one rotation of each of the eccentric weight gears 62A and 62B. That is, after this one rotation, the eccentric weight gears 62A and 62B are arranged so that the eccentric weights 64 are faced exactly opposite to each other in the radial direction of the rotation center line LC, as shown in FIG. 9A.

Each of the sample stages 36A and 36B, together with each centrifugal separating-distributing apparatus 10, rotated counterclockwise or clockwise by 90° from the second rotation angle position shown in FIG. 9B is returned to the first rotation angle position shown in FIG. 9A. In this time, the centrifugal force generator 30 is reset to the initial state shown in FIG. 9A.

Thereafter, the centrifugal separating-distributing apparatuses 10 are removed from the sample stages 36A and 38B, and the vessel holding members 26 are removed from the centrifugal separating-distributing apparatuses 10. The vessels 22 can be removed from the removed vessel holding member 26. Refer to FIG. 3E.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A centrifugal separating-distributing apparatus comprising:
a sample intake path configured to be taken with a fluid sample to be centrifugally separated, and having a fluid sample outlet through which the fluid sample flows out when a first centrifugal force is exerted at a first rotation angle position;
a separated-component stacking path having a fluid sample inlet through which the fluid sample flowed out from the outlet of the sample intake path by the first centrifugal force flows in, and configured to separate the fluid sample into a plurality of components and to stack the separated components by the first centrifugal force; and
a distributing path having a separated component inlet positioned between the outlet of the sample intake path and the inlet of the separated-component stacking path, and configured to be distributed with a component from the components stacked in the separated-component stacking path when a second centrifugal force is exerted at a second rotation angle position.

2. The apparatus according to claim 1, wherein:
a first angle formed between a direction in which the fluid sample moves toward the outlet in the sample intake path and a direction in which the first centrifugal force is exerted, is less than 90°;
a second angle formed between a direction in which the components separated from the fluid sample are stacked in the separated-component stacking path and the direction in which the first centrifugal force is exerted, is less than 90°;
a third angle formed between a direction in which the component distributed into the distributing path is moved away from the separated component inlet and the direction in which the first centrifugal force is exerted, while the first centrifugal force is exerted, is greater than or equal to 90° and less than 180°; and
a total of the first angle and third angle is less than 180°.

3. The apparatus according to claim 2, wherein:
a fourth angle formed between the direction in which the separated-components are stacked in the separated-component stacking path and a direction in which the second centrifugal force is exerted, while the second centrifugal force is exerted, is less than 90°; and
a fifth angle formed between the direction in which the component distributed into the distributing path is moved away from the separated component inlet and the direction in which the second centrifugal force is exerted, while the second centrifugal force is exerted, is less than 90°.

4. The apparatus according to claim 1, wherein:
an angle formed between the direction in which the first centrifugal force is exerted and a tangential vector generated at any position on an inner surface of the sample intake path by the fluid sample moving toward the outlet of the sample intake path, is less than 90°;
an angle formed between the direction in which the first centrifugal force is exerted and a tangential vector generated at any position on an inner surface of the separated-component stacking path by the components separated from the fluid sample and stacked in the separated-component stacking path, is less than 90°;
an angle formed between the direction in which the first centrifugal force is exerted and a tangential vector generated at any position on an inner surface of the distributing path by the component distributed into the distributing path and moved away from the separated component inlet in the distributing path, while the second centrifugal force is exerted, is greater than or equal to 90° and less than 180°;
an angle formed between the direction in which the second centrifugal force is exerted and the tangential vector generated at any position on the inner surface of the separated-component stacking path by the components separated from the fluid sample and stacked in the separated-component stacking path, is less than 90°; and
an angle formed between the direction in which the second centrifugal force is exerted and a tangential vector generated at any position on the inner surface of the distributing path by the component distributed into the distributing path and moved away from the separated component inlet, while the second centrifugal force is exerted, is less than 90°.

5. The apparatus according to claim 1, wherein,
while the second centrifugal force is exerted, a surface, which is closest to the fluid sample inlet, in the remainder of the components stacked in the separated-component stacking path is positioned at the same position as that of the fluid sample inlet or at a position in a direction moving away from the fluid sample inlet in the direction in which the second centrifugal force is exerted, so that the remainder does not flow into the separated component inlet of the distributing path over the fluid sample inlet both before and after the second centrifugal force is exerted.

6. The apparatus according to claim 1, wherein,
at a position far from the separated component inlet in the distributing path, at least one predetermined-capacity vessel is removably provided to store the component distributed into the distributing path from the separated component inlet and moved away from the separated component inlet, while the second centrifugal force is exerted.

7. The apparatus according to claim 6, wherein predetermined-capacity vessels are removably provided at a position far from the separated component inlet in the distributing path to store the component distributed into the distributing path from the separated component inlet and moved away from the separated component inlet when the second centrifugal force is exerted; and
the vessels are arranged in a direction crossing the moving direction of the component moved away from the separated component inlet in the distributing path.

8. The apparatus according to claim 6, wherein predetermined-capacity vessels are removably provided at a position far from the separated component inlet in the distributing path to store the component distributed into the distributing path from the separated component inlet and moved away from the separated component inlet when the second centrifugal force is exerted; and
the vessels are arranged in a direction along the moving direction of the component moved away from the separated component inlet in the distributing path.

9. The apparatus according to claim 8, wherein the vessels are arranged adjacent to each other in the component moving direction, and have distributed sample pots connected to each other in the moving direction.

10. The apparatus according to claim 1, further comprising a sealing plug removably provided at a position in the separated-component stacking path, the position being far from the fluid sample inlet in the direction in which the components separated from the fluid sample are stacked in the fluid sample inlet; and
wherein the separated-component stacking path is connected to the outside space through the far position, when the plug is separated from the far position.

11. A centrifugal force generator comprising:
a rotation drive source;
a rotation member configured to rotate about a predetermined rotation center line by a rotation force transmitted from the rotation drive source;
at least a pair of sample stages arranged symmetrically with respect to the rotation center line on the rotation member and revolved around the rotation center line by the rotation of the rotation member, each sample stage supporting removably the centrifugal separating-distributing apparatus according to one of claim 1-9 so that the sample intake path, the separated-component stacking path and the distributing path of the apparatus are arranged in a plane crossing the rotation center line; and
a sample stage rotation mechanism configured to rotate at least the pair of sample stages in directions exactly opposite to each other between a predetermined first rotation angle position and a predetermined second rotation angle position;
wherein the sample intake path, the separated-component stacking path, and the distributing path of each centrifugal separating-distributing apparatus supported by each sample stage so perform that: first, when the rotation member is rotated in a state that each sample stage is placed at the first rotation angle position, a fluid sample in the sample intake path is flowed into the separated-component stacking path through the fluid sample outlet by a first centrifugal force exerted on the fluid sample in the sample intake path, the fluid sample flown into the separated-component stacking path is separated into a plurality of components and the components are stacked by the first centrifugal force;
secondary, by rotating each of the sample stages from the first rotation angle position to the second rotation angle position, a component closest to the fluid sample inlet among the stacked components in the separated-component stacking path is distributed into the distributing path from the separated component inlet, and
thirdly, when the rotation member is rotated after each sample stage is rotated from the first rotation angle to the second rotation angle position, the distributed component is moved away from the separated component inlet, is separated from the remainder of the stacked components in the separated-component stacking path and the separated component is collected, by the second centrifugal force.

12. The generator according to claim 11, further comprising at least a pair of eccentric members, each rotatably provided on each rotation member, provided with an eccentric weight eccentric with respect to a rotation center line of each member, rotated by the rotation of each sample stage between the first rotation angle position and the second rotation angle position by the sample rotation mechanism, and arranging each eccentric weight in an outside of the rotation center line of each eccentric member to the rotation center of the rotation member on a straight line passing through the rotation center line of the rotation member and the rotation center line of each eccentric member when each sample stage is placed at any of the first rotation angle position and the second rotation angle position.

13. The generator according to claim 12, wherein, in the rotation member, the rotation center of each eccentric member is placed farther from each sample stage from the rotation center line of the rotation member on a straight line passing through the rotation center line of the rotation member and the rotation center line of each sample stage.

14. A centrifugal separating-distributing method comprising:
preparing a centrifugal separating-distributing apparatus comprising a sample intake path, a separated-component stacking path and a distributing path,
one end of each of these paths being connected each other,
the sample intake path having the other end through which a fluid sample to be centrifugally separated is taken,
the separated-component stacking path having the other end closed,
the distributing path having the other end to which at least one of a predetermined volume vessel is detachably attached,
the sample intake path and the separated-component stacking path being so arranged
to make the fluid sample in the sample intake path flow out from its one end as a fluid sample outlet and flow into the separated-component stacking path through its one end as a fluid sample inlet when a first centrifugal force directing in a predetermined direction is exerted on the fluid sample in the sample intake path, and
to make the fluid sample in the separated-component stacking path separate a plurality of components from the fluid sample and stack the separated components in the other end of the separated-component stacking path by exerting the first centrifugal force on the fluid sample in the separated-component stacking path, and
the distributing path being so arranged to be distributed with a component being closest to the fluid sample inlet at the one end of the separated-component stacking path in the separated and stacked components in the separated-component stacking path, from the separated component inlet when a second centrifugal force is exerted after the plurality of components is stacked in the other end of the separated-component stacking path, and to make the distributed component move away from the separated component inlet, separate from the remaining components in the separated-component stacking path and being collected in the predetermined volume vessel by exerting the second centrifugal force on the separated component;
taking the fluid sample to be centrifugally separated into the other end of the sample intake path;
exerting the first centrifugal force on the fluid sample in the sample intake path of the centrifugal separating-distributing apparatus to make the fluid sample in the sample intake path flow out from its one end as the fluid sample outlet and flow into the separated-component stacking path through its one end as the fluid sample inlet;
further exerting the first centrifugal force on the fluid sample flown into the separated-component stacking path to separate the flown-in fluid sample into the plurality of component and to stack the separated components in the other end of the separated-component stacking path in a direction in which the first centrifugal force is exerted;
exerting the second centrifugal force on the stacked components in the other end of the separated-component stacking path to distribute the component being closest to the fluid sample inlet at the one end of the separated-component stacking path, in the separated and stacked components in the separated-component stacking path, through the separated component inlet at the one end of the distributing path;
further exerting the second centrifugal force on the distributed component to make the distributed component move away from the separated component inlet, to separate the distributed component from the remaining and stacked components in the separated-component stacking path, and to make the distributed component being collected in the at least one of predetermined volume vessel at the other end of the distributing path; and
removing the at least one predetermined volume vessel in which the component is collected from the other end of the distributing path.
